(19) United States
(12) Patent Application Publication
(10) Pub. No.: US 2023/0079712 A1
(43) Pub. Date: Mar. 16, 2023

(54) MASK FRAME AND EVAPORATION MASK ASSEMBLY

(71) Applicant: KunShan Go-Visionox Opto-Electronics Co., Ltd, Kunshan (CN)

(72) Inventors: Weili LI, Kunshan (CN); Yue QIU, Kunshan (CN)

(73) Assignee: KunShan Go-Visionox Opto-Electronics Co., Ltd, Kunshan (CN)

(21) Appl. No.: 17/989,089

(22) Filed: Nov. 17, 2022

Related U.S. Application Data
(63) Continuation of application No. PCT/CN2021/109906, filed on Jul. 30, 2021.

(30) Foreign Application Priority Data
Sep. 30, 2020 (CN) 202011061713.0

(51) Int. Cl. H01L 51/00; C23C 14/04; C23C 14/24; H01L 51/56

(52) U.S. Cl. CPC H01L 51/0011; C23C 14/042; C23C 14/24; H01L 51/001; H01L 51/56

(57) ABSTRACT

A mask frame and an evaporation mask assembly. The mask frame has a first surface and a second surface facing away from each other and includes: a frame body, which is formed as a frame structure with an opening; and a support body, provided in the opening and connected to the frame body. The support body includes a plurality of evaporation apertures distributed in an array and a plurality of support units distributed around the evaporation apertures, each support unit includes a supporting portion and a bonding portion extending from the supporting portion toward the evaporation apertures, the supporting portion includes a supporting surface located on the first surface, the bonding portion includes a bonding surface protruding to the second surface in a first direction from the first surface to the second surface.

### CROSS REFERENCE TO RELATED APPLICATIONS

This application is a continuation of PCT Application No. PCT/CN2021/109906, which is filed on Jul. 30, 2021 and claims the priority of Chinese Patent Application No. 202011061713.0, filed on Sep. 30, 2020 and entitled “Mask Frame and Evaporation Mask Assembly”, both of which are incorporated herein by reference in their entireties.

### TECHNICAL FIELD

The application relates to the technical field of evaporation equipment, and in particular to a mask frame and an evaporation mask assembly.

### BACKGROUND

Currently, OLED (Organic Light-Emitting Diode) display panel has become a key research product in the display field. In the manufacturing process of the OLED display panel, the devices for evaporation, especially the mask frame and the mask, are crucial components that affect the production cost and product quality of the OLED display panel.

When FMM is displaced on the mask frame, due to the misalignment between the effective evaporation area of the FMM and the to-be-evaporated area of the substrate or the increase of shadows, the evaporation accuracy is poor, causing undesirable phenomena such as color mixing in the OLED display panel and reduction of the product yield.

Therefore, there is an urgent need for a new type of mask frame and an evaporation mask assembly.

### SUMMARY

In one aspect, the embodiments of the present application provide a mask frame, having a first surface and a second surface opposite to each other. The mask frame includes a frame body and a support body. The frame body is formed as a frame structure with an opening. The support body is arranged in the opening and connected to the frame body. The support body includes a plurality of evaporation apertures distributed in an array and a plurality of support units distributed around the respective evaporation apertures. The support unit includes a supporting portion and a bonding portion extending from the supporting portion toward the evaporation aperture. The supporting portion includes a supporting surface located on the first surface. The bonding portion includes a bonding surface protruding to the second surface in a first direction from the first surface to the second surface, and the bonding surface and the supporting surface is distributed in a stepped shape with the supporting surface.

The use of the mask frame in the evaporation process saves the steps of aligning a plurality of supporting strips and shielding strips in a net stretching manner and welding and fixing them in the process of manufacturing the mask frame, and shortens the time for manufacturing the mask frame, thereby further shortening the time required for the evaporation process, and improving the production efficiency of the entire OLED display panel.

In an example, the mask frame may form the frame body and the support body by etching a plate, and the material of the plate may be a metal material. In another example, the mask frame forms the supporting portion and the bonding portion of the support unit by electroforming on a plate provided with a plurality of evaporation apertures arranged in an array.

The mask frame in the embodiments of the present application is formed without the need of aligning a plurality of supporting strips and shielding strips in the net stretching manner and welding and fixing them to the frame body, and the supporting portion can simultaneously realize the supporting function to the mask strip and the shielding function to the evaporation area on the substrate, which shortens the time required for the evaporation process, improves the production efficiency of the display panel, and reduces the production cost. The bonding portion in the mask frame includes a bonding surface, the bonding surface protrudes to the second surface in the first direction from the first surface to the second surface, and the bonding surface and the supporting surface is distributed in a stepped shape with the supporting surface.

In some examples, the peripheral edges of the effective evaporation area of the mask strip which includes a plurality of evaporation holes, are located at the bonding portions, so that the mask strip can be better bonded with the mask frame in the first aspect of the embodiments of the present application, and thus the alignment accuracy of the effective evaporation area on the mask strip with the corresponding evaporation aperture on the mask frame is improved, thereby improving the evaporation accuracy and being beneficial to improve the display quality of the display panel.

Since the evaporation apertures on the mask frame in the embodiments of the present application are formed without the need of a plurality of crisscrossing shielding strips and supporting strips, the deviations of the position and opening accuracy of the evaporation apertures on the mask frame caused by the misalignment of the shielding strips and supporting strips during the net stretching process can be avoided. The alignment accuracy between the effective evaporation area of the mask strip with the evaporation aperture on the mask frame is improved when the mask strip is fixed to the mask frame.

On the other hand, the embodiments of the present application further provide an evaporation mask assembly, including:

a mask frame according to any of the embodiments on one aspect of the present application; and

a plurality of the mask strips arranged on the mask frame, the mask strip includes two fixing structures respectively disposed at two ends thereof in its length direction and an evaporation mesh film located between the fixing structures, and the evaporation mesh film includes a plurality of evaporation holes arranged in an array,

wherein the mask strip is fixed to the frame body through the fixing structures, the evaporation mesh film covers the first surface, and two sides of the evaporation mesh film in its length direction are arranged in contact with the supporting surfaces of the supporting portions.

The mask frame provided by another aspect of the embodiments of the present application supports the evaporation mesh film through the supporting portion, and the supporting portion can simultaneously support the mask strip and shield the non-evaporated area on the substrate; the evaporation mesh film is bonded to the mask frame through the bonding portion, and the evaporation mesh film is formed with the effective evaporation area corresponding to each evaporation aperture. The mask strip provided with the evaporation mesh film changes the previous structure that provides multiple effective evaporation areas and other functional areas outside and surrounding the effective evaporation areas, thereby avoiding the existence of boundaries between different areas on the mask strip, avoiding the mask strip from being wrinkled at different areas, especially at the boundaries between different areas of the mask strip, during the process of fixing the mask strip to the mask frame in the net stretching manner, increasing the bonding degree between the mask strip and the mask frame, improving the evaporation accuracy of the evaporation material evaporated to the to-be-evaporated area of the substrate through the mask strip, improving the quality of substrate evaporation, and improving the display effect of the display panel.

In some embodiments of another aspect of the present application, the mask frame further includes a plurality of auxiliary structures formed on the bonding portion and extending from the bonding surface toward the first surface, the plurality of auxiliary structures are distributed at intervals around the evaporation aperture on the bonding surface, and a sum of a thickness of the bonding portion and an extending height of the auxiliary structure in the first direction is equal to a thickness of the supporting portion.

The evaporation mesh film covers the first surface, and each of the two sides of the evaporation mesh film in its length direction is arranged in contact with both the supporting surfaces of the supporting portions and auxiliary supporting surfaces of the auxiliary structures located on the first surface.

On the bonding portion, the plurality of auxiliary structures distributed at intervals around the evaporation aperture are arranged, so that the wrinkles on the mask strip, especially the mask strip including the evaporation mesh film, generated due to the tensile stress in the net stretching process, are stretched, and thus the amount of the wrinkles on the mask strip is reduced, the alignment precision and accuracy of the effective evaporation area formed corresponding to the evaporation aperture with the to-be-evaporated area on the substrate are improved, and the evaporation accuracy of the evaporation process is improved, thereby avoiding the display color mixing and other undesirable phenomena of the OLED display panel, optimizing the display effect of the display panel and improving the product yield of the display panel.

### BRIEF DESCRIPTION OF THE DRAWINGS

The features, advantages, and technical effects of exemplary embodiments of the present application will be described below with reference to the accompanying drawings, which are not drawn to actual scale.

FIG. 1 is a schematic structural diagram of a mask frame provided in an embodiment of the first aspect of the present application;

FIG. 2 is a sectional view along M-M direction of FIG. 1;

FIG. 3 is a schematic structural diagram of a first mask strip in an embodiment of the second aspect of the present application;

FIG. 4 is a schematic structural diagram of an evaporation mask assembly provided by an embodiment of the second aspect of the present application;

FIG. 5 is a schematic structural diagram of a second mask strip in an embodiment of the second aspect of the present application;

FIG. 6 is a schematic structural diagram of an evaporation mask assembly provided by another embodiment of the second aspect of the present application;

FIG. 7 is a schematic structural diagram of a mask frame provided by another embodiment of the first aspect of the present application;

FIG. 8 is a partial enlarged view of the portion A in FIG. 7;

FIG. 9 is a cross-sectional view of FIG. 7 along N-N direction; and

FIG. 10 is a schematic structural diagram of an evaporation mask assembly provided by still another embodiment of the second aspect of the present application.

### DETAILED DESCRIPTION

The features and exemplary embodiments in various aspects of the present application will be described in detail below. In the following detailed description, many specific details are proposed to provide a comprehensive understanding of the present application. However, it is obvious to the person skilled in the art that the present application can be implemented without some of these specific details. The following description of the embodiments is only to provide a better understanding of the present application by showing examples of the present application. In the accompanying drawings and the following description, at least part of the well-known structures and technologies are not shown to avoid unnecessary obscuring of the present application; and, for clarity, the size of some structures may be exaggerated. In addition, the features, structures, or characteristics described below may be combined in one or more embodiments in any suitable manner.

For a better understanding of the present application, a mask frame and an evaporation mask assembly provided by the embodiments of the present application will be described in detail below with reference to the accompanying drawings.

When manufacturing an OLED display panel, a mask used in a process of forming a luminescent material layer by evaporation mainly includes a long strip Fine Metal Mask (FMM), which can also be called a mask strip. Usually, during the evaporation process, the FMM is fixed on a mask frame, and the mask frame is provided with a plurality of supporting strips and a plurality of shielding strips extending vertically and horizontally on a side of the FMM facing away from a substrate, to support the FMM and shield non-evaporation areas of the substrate, so that an evaporation material is evaporated on to-be-evaporated areas of the substrate through FMM to form the luminescent material layer. During research, the inventor found that, since in a general process of manufacturing the mask frame, it is necessary to align a plurality of supporting strips and a plurality of shielding strips respectively in a net stretching manner and welding them to a frame body with an opening, the manufacturing process takes a long time, resulting in low production efficiency of the OLED display panel and great time cost in the production process. Further, inaccurate alignment of the plurality of supporting strips and shielding strips are easy to occur during the fixing process of the net stretching, thereby affecting the positional accuracy of the evaporation apertures arranged in an array and formed by crisscross supporting strips and shielding strips. Moreover, because each evaporation aperture corresponds to each effective evaporation area on the mask strip, the inaccurate position of the evaporation aperture affects the evaporation accuracy of the evaporation material in the entire evaporation process from the evaporation aperture to the effective evaporation area on the mask strip, and then to the to-be-evaporated area on the substrate, and ultimately affects the display quality of the OLED display panel.

Generally, the remaining functional areas on the mask strip except and surrounding the effective evaporation areas have different structures from the effective evaporation areas, so that there are area boundaries between different areas on the mask strip. The mask strip is wrinkled due to the tensile stress during the net stretching process, and in turn, the stress generated in the mask strip by the tensile force will produce a sudden change of stress at the above-mentioned area boundaries and the vicinity thereof, resulting in that the mask strip is more likely to be wrinkled at the area boundaries and the vicinity thereof. Wrinkles on the mask strip, especially on the boundaries of the effective evaporation areas, lower the alignment accuracy of the effective evaporation areas with the to-be-evaporated areas of the substrate, affect the shape and structure of the effective evaporation areas, and further lead to low accuracy of the evaporation process, thereby causing problems such as color mixing and shadowing, and affecting the display effect of the display panel.

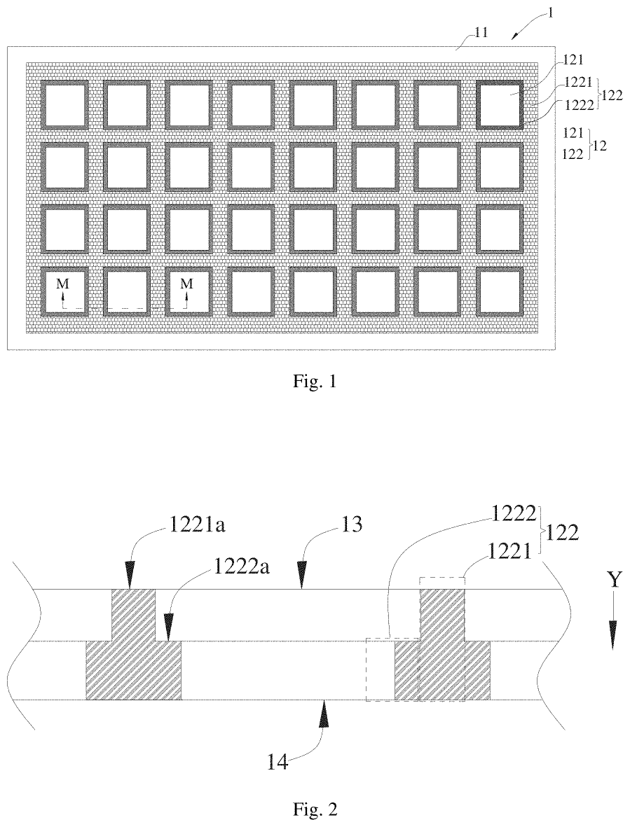

Referring to FIG. 1 and FIG. 2, the mask frame 1 provided in the first aspect of the embodiments of the present application has a first surface 13 and a second surface 14 opposite to each other, and the mask frame 1 includes a frame body 11 and a support body 12. The frame body 11 is formed as a frame structure with an opening. The support body 12 is arranged in the opening and connected to the frame body 11. The support body 12 includes a plurality of evaporation apertures 121 distributed in an array and a plurality of support units 122 distributed around the respective evaporation apertures 121. The support unit 122 includes a supporting portion 1221 and a bonding portion 1222 extending from the supporting portion 1221 toward the evaporation aperture 121. The supporting portion 1221 includes a supporting surface 1221a located on the first surface 13, the bonding portion 1222 includes a bonding surface 1222a protruding to the second surface 14 in a first direction Y from the first surface 13 to the second surface 14, and the bonding surface 1222a and the supporting surface 1221a and is formed in a stepped shape with the supporting surface 1222a.

The supporting portion 1221 in the mask frame 1 according to the embodiments of the first aspect of the present application can simultaneously support the mask strip and shield the non-evaporation area on the substrate, thereby saving the alignment in the net stretching manner and the welding and fixing process of multiple support strips and shielding strips, shortening the time required for the evaporation process, improving the production efficiency of the display panel, and reducing the production cost.

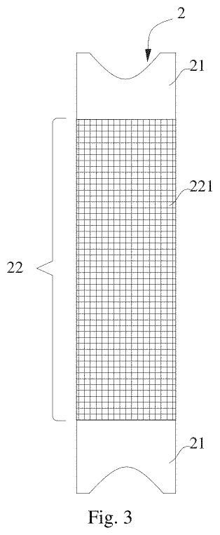

Referring to FIG. 3, in the embodiments of the second aspect of the present application, a first mask strip 2 includes two first fixing structures 21 respectively disposed at two ends thereof in its length direction and an evaporation mesh film 22 located between the first fixing structures 21, and the evaporation mesh film 22 includes a plurality of first evaporation holes 221 arranged in an array. During the evaporation process, the evaporation material is evaporated onto the evaporation substrate through the above-mentioned first evaporation holes 221. As shown in FIG. 3, the evaporation mesh film 22 in the first mask strip 2 is formed as a full through-hole structure.

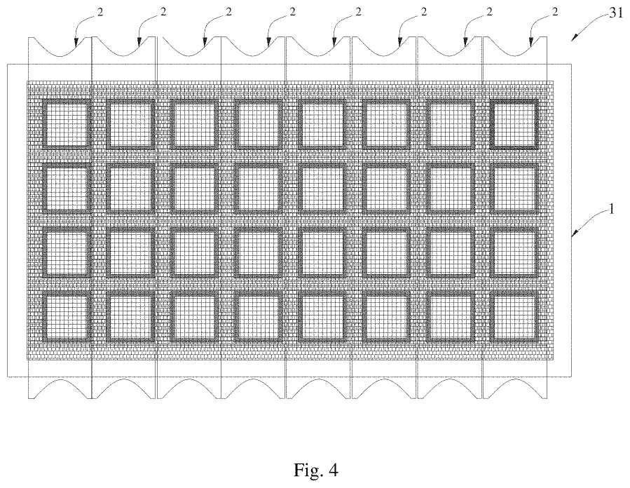

Referring to FIGS. 1 to 4 in combination, a first evaporation mask assembly 31 according to the second aspect of the embodiments of the present application includes a mask frame 1 and a plurality of first mask strips 2. The plurality of first mask strips 2 are arranged on the mask frame 1. The first mask strip 2 as shown in FIG. 3 is fixed to the frame body 11 through the first fixing structures 21. The evaporation mesh film 22 covers the first surface 13, and two sides of the evaporation mesh film 22 in its length direction are arranged in contact with the supporting surfaces 1221a of the supporting portions 1221.

The mask frame 1 as shown in FIG. 1 and FIG. 2 supports the evaporation mesh film 22 in the first mask strip 2 as shown in FIG. 3 through the supporting portions 1221, and the supporting portions 1221 can simultaneously realize the supporting function to the first mask strip 2 and the shielding function to the non-evaporation area on the evaporation substrate. The evaporation mesh film 22 is bonded to the mask frame 1 through the bonding portion 122, and forms the effective evaporation area corresponding to each evaporation aperture 121. The first mask strip 2 provided with the evaporation mesh film 22 changes the previous structure that provides multiple effective evaporation areas and other functional areas outside and surrounding the effective evaporation areas, thereby avoiding the existence of boundaries between different areas on the mask strip, and avoiding the mask strip from being wrinkled at different areas, especially at the boundaries between different areas, of the mask strip during the process of fixing the mask strip to the mask frame in the net stretching manner. The first mask strip 2 provided with the evaporated mesh film 22 increases the bonding degree between the mask strip and the mask frame, improves the evaporation accuracy of the evaporation material evaporated to the to-be-evaporated area of the substrate through the mask strip, improves the quality of substrate evaporation, and improves the display effect of the display panel.

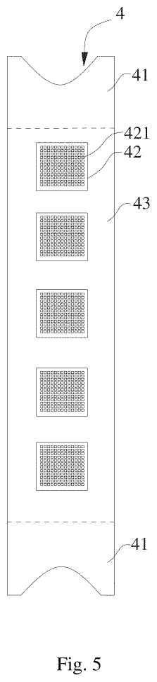

Referring to FIG. 5, FIG. 5 is a schematic structural diagram of a second mask strip 4 in the embodiments of the present application. As shown in FIG. 5, the second mask strip includes two second fixing structures 41 respectively disposed at two ends thereof in its length direction. The second mask strip 4 includes a plurality of effective evaporation areas 42 arranged at intervals in its length direction, and a non-evaporation area 43 surrounding the effective evaporation areas 42. A plurality of second evaporation holes 421 are provided in the pattern evaporation area 42, and the evaporation material is evaporated onto the evaporation substrate through the plurality of second evaporation holes 421 in the evaporation process.

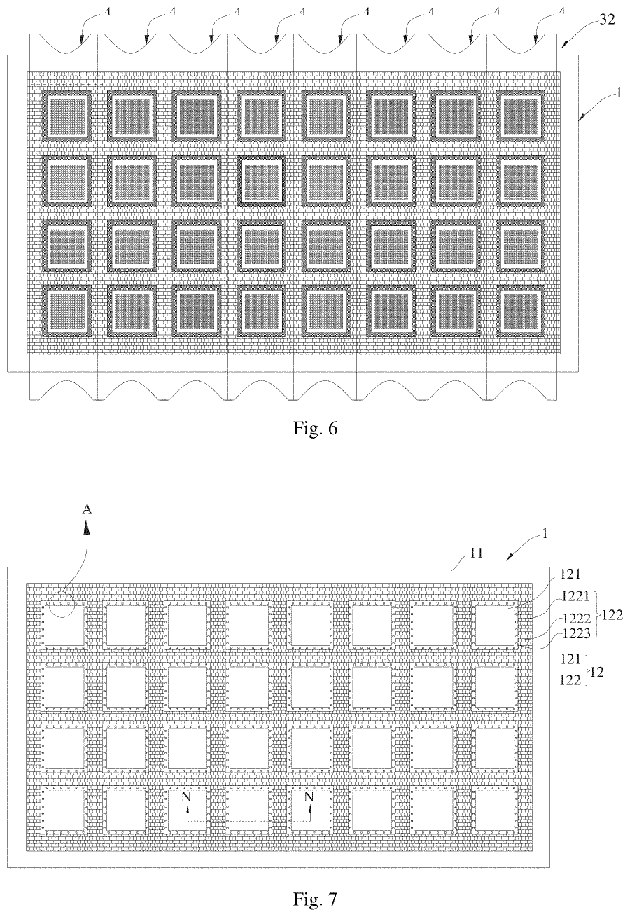

Referring to FIG. 6, FIG. 6 is a second evaporation mask assembly 32 provided by another embodiment of the second aspect of the present application. As shown in FIG. 6, the evaporation mask assembly 32 includes: the mask frame 1 as shown in FIG. 1 and FIG. 2 and a plurality of second mask strips 4 as shown in FIG. 5. The plurality of second mask strips 4 are arranged on the mask frame 1. The second mask strip 4 is fixed to the frame body 11 by the second fixing structures 41. Peripheral edges of the effective evaporation area 42 of the second mask strip 4 which is provided with a plurality of second evaporation holes 421 are located on the bonding portions 1222, so that the second mask strip 4 is better bonded with the mask frame 1 in the embodiments of the present application, thereby improving the alignment accuracy of the effective evaporation area 42 on the second mask strip 4 with the corresponding evaporation aperture 121 on the mask frame 1. Moreover, the bonding portions 1222 can stretch the wrinkles formed between the effective evaporation areas 42 and the non-evaporation area 43, thereby further improving the alignment and bonding accuracy of the effective evaporation areas 42 with the evaporation apertures, improving the evaporation accuracy, and thus being beneficial to the display quality of the display panel.

In some optional embodiments, the thickness of the frame body 11 in the first direction Y is the same as the thickness of the supporting portion 1221, and the thickness of the bonding portion 1222 is smaller than that of the supporting portion 1221.

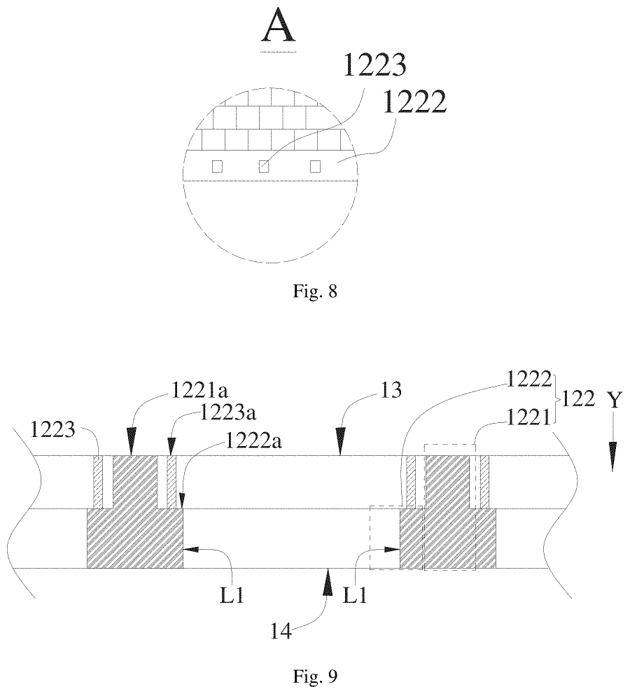

Referring to FIGS. 7 to 9, in some optional embodiments, the mask frame further includes a plurality of auxiliary structures 1223 formed on the bonding portion 1222 of the mask frame 1 and extending from the bonding surface 1222a toward the first surface 13, and the plurality of the auxiliary structures 1223 are distributed at intervals around the evaporation aperture 121 on the bonding surface 1222a.

In some optional embodiments, the auxiliary structure 1223 is spaced apart from the supporting portion 1221 in a horizontal direction parallel to the first surface 13. The spacing distance is greater than or equal to 2 mm. When the areas with wrinkles on the mask strip (for example, the first mask strip 2 or the second mask strip 4) cover the plurality of auxiliary structures 1223, multiple support points produce a supporting effect on different areas of the wrinkles. The auxiliary structures 1223 apply supporting forces opposite to the first direction Y to the wrinkles, and the area of the wrinkles located between two adjacent auxiliary structures 1223 sinks toward the first direction Y due to the action of gravity. Further, the auxiliary structure 1223 and the supporting portion 1221 are spaced apart from each other, and the space between the auxiliary structure 1223 and the supporting portion 1221 can accommodate the sinking areas of the wrinkles, thereby providing enough stretching space for the wrinkles between the auxiliary structure 1223 and the supporting portion 1221, and thus facilitating the stretching of the wrinkles on the mask strip 2.

In some optional embodiments, referring to FIG. 9, the sum of the thickness of the bonding portion 1222 and the extending height of the auxiliary structure 1223 in the first direction Y is equal to the thickness of the supporting portion 1221. Then, the auxiliary structure 1223 has an auxiliary supporting surface 1223a on the first surface 13, which is located at the same level as the supporting surface 1221a of the supporting portion 1221. The auxiliary supporting surface 1223a not only stretches the wrinkles of the mask strip (such as the first mask strip 2 and the second mask strip 4), but also supports the mask strip at the same level as the supporting surface 1221a of the supporting portion 1221. Thus, during the evaporation process, the mask strip is bonded with the evaporation substrate better, and the gap between the evaporation substrate and the mask strip is narrowed. The distance between the effective evaporation area on the mask strip and the to-be-evaporated area is further shortened, and the alignment accuracy of the effective evaporation area with the to-be-evaporated area is improved, while the shadow effect is weakened, and a smaller amount of sublimated organic material molecules will be deposited outside the to-be-evaporated area.

In some optional embodiments, the bonding surface 1222a includes a first edge L1 adjacent to the evaporation aperture 121, and the auxiliary structure 1223 is arranged with a predetermined distance from the first edge L1 in the horizontal direction parallel to the first surface 13. The arrangement of the predetermined distance can ensure the availability of the coverage area for material evaporation. The predetermined distance is greater than or equal to 2 mm.

In some optional embodiments, the auxiliary structure 1223 is formed as a columnar body, and the columnar body has a cross section in a circular or a polygonal shape.

In some optional embodiments, the thickness of the frame body 11 in the first direction Y is equal to a minimum distance between the first surface 13 and the second surface 14.

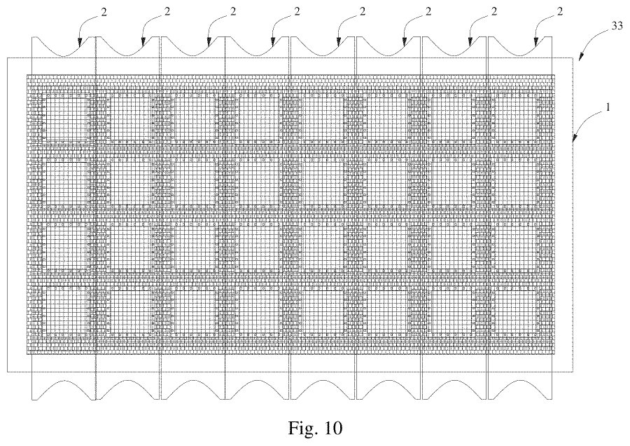

FIG. 10 shows a third evaporation mask assembly 33 provided by a still another embodiment of the second aspect of the present application. As shown in FIG. 10, the third evaporation mask assembly 33 includes: the mask frame 1 as shown in FIG. 7 to FIG. 9 and a plurality of first mask strips 2 as shown in FIG. 3. The plurality of first mask strips 2 are arranged on the mask frame 1. The first mask strip 2 is fixed to the frame body 11 through the second fixing structures 41.

In the third evaporation mask assembly 33, the evaporation mesh film 22 in the first mask strip 2 as shown in FIG. 3 covers the first surface 13 of the mask frame 1 as shown in FIG. 7 to FIG. 9. Further, each of two sides of the evaporation mesh film 22 in its length direction is arranged in contact with both supporting surfaces 1221a of the supporting portions 1221 and the auxiliary supporting surfaces 1223a of the auxiliary structures 1223 located on the first surface 13. As a result, the supporting portions 1221 and the auxiliary structures 1223 both have the supporting effect to the mask strip. The plurality of auxiliary structures 1223 are arranged at intervals around the evaporation aperture 121, so as to be distributed around the evaporation aperture 121 in a point-breaking manner. The plurality of auxiliary structures 1223 provide a plurality of supporting points for the first mask strip 2 covering them, and the respective supporting points not only support the first mask strip 2, but also can stretch the wrinkles on the first mask strip 2 by the supporting functions of the plurality of supporting points and the accommodating functions of the space between the supporting points. The auxiliary structures 1223 facilitate the wrinkles formed due to the net stretching of the first mask strip 2 to be stretched during the process of fixing the first mask strip 2 to the mask frame 1, thereby improving the bonding degree between the first mask strip 2 and the mask frame 1. The arrangement of the auxiliary structures 1223 reduces the gap between the first mask strip 2 and the evaporation substrate during the evaporation process, avoids the shadow effect of evaporation, and improves the quality of evaporation, thereby improving the production quality of the display panel and optimizing the display effect of the display panel.

Further, the evaporation mesh film 22 in the first mask strip 2 has a full through-hole structure, and does not include the area boundaries between the effective evaporation areas 42 and the non-evaporation area 43 compared with the second mask strip 4, the actual evaporation area of the mask strip 2 is constituted by the area of the evaporation mesh film 22 corresponding to the evaporation apertures 121. Therefore, since the first mask strip 2 is not subjected to the stress at the area boundaries between different functional areas on the mask strip during the process of net stretching, the probability and amount of wrinkles generated during the process of net stretching of the first mask strip 2 is less than the second mask strip 4, thereby further improving the alignment precision and accuracy of the third evaporation mask assembly 33 with the to-be-evaporated area of the evaporation substrate. Thus, the evaporation accuracy of the evaporation process is improved, undesirable phenomena such as display color mixing of the OLED display panel is avoided, the display effect of the display panel is optimized, and the product yield of the display panel is improved.

The support units 122 in the mask frame 1 as shown in FIG. 7 to FIG. 9 also limit and control the drooping amount of the evaporated mesh film 22 when the first mask strip 2 is arranged on the mask frame 1, so as to avoid the evaporation holes 221 and the evaporation mesh film 22 from deforming due to their own gravities and/or the pressure of the evaporation substrate when the evaporation mesh film 22 is bonded to the mask frame 1. Therefore, the evaporation accuracy is further ensured, the product yield of the display panel during the evaporation process is improved, the problems such as color mixing of the display panel are avoided, and the display effect of the display panel is improved.

The person skilled in the art should understand that the above-mentioned embodiments are all illustrative and not restrictive. Different technical features appearing in different embodiments can be combined to achieve beneficial effects. The person skilled in the art should be able to understand and implement other variant embodiments of the disclosed embodiments on the basis of studying the accompanying drawings, the specification and the claims. In the claims, the term “comprising” does not exclude other means or steps; an item, when not modified by a quantifier, is intended to include one/one kind or more/more kinds of items, and may be used interchangeably with “one/one kind or more/more kinds of items; the terms “first”, “second” are used to designate names rather than to indicate any particular order. Any reference signs in the claims should not be construed as limiting the scope of protection. The functions of multiple parts appearing in the claims can be realized by a single hardware or software module. The appearance of certain technical features in different dependent claims does not mean that these technical features cannot be combined to achieve beneficial effects.

What is claimed is:

1. A mask frame, having a first surface and a second surface opposite to each other, and comprising:
a frame body, formed as a frame structure with an opening;
a support body, arranged in the opening and connected to the frame body, the support body comprising a plurality of evaporation apertures distributed in an array and a plurality of support units distributed around the respective evaporation apertures, the support unit comprising a supporting portion and a bonding portion extending from the supporting portion toward the evaporation aperture, the supporting portion comprising a supporting surface located on the first surface, the bonding portion comprising a bonding surface protruding to the second surface in a first direction from the first surface to the second surface, and the bonding surface and the supporting surface are distributed in a stepped shape.

2. The mask frame according to claim 1, wherein in the first direction, a thickness of the frame body is the same as a thickness of the supporting portion, and a thickness of the bonding portion is smaller than that of the supporting portion.

3. The mask frame according to claim 1, further comprising a plurality of auxiliary structures formed on the bonding portion and extending from the bonding surface toward the first surface, wherein the auxiliary structures are distributed at intervals around the evaporation aperture on the bonding surface.

4. The mask frame according to claim 3, wherein a sum of a thickness of the bonding portion and an extending height of the auxiliary structure in the first direction is equal to a thickness of the supporting portion.

5. The mask frame according to claim 3, wherein the auxiliary structure is spaced apart from the supporting portion in a horizontal direction parallel to the first surface.

6. The mask frame according to claim 3, wherein the bonding surface comprises a first edge adjacent to the evaporation aperture, and the auxiliary structure is arranged with a predetermined distance from the first edge in a horizontal direction parallel to the first surface.

7. The mask frame according to claim 6, wherein the predetermined distance is greater than or equal to 2 mm.

8. The mask frame according to claim 3, wherein the auxiliary structure is formed as a columnar body, and the columnar body has a cross section in a circular or polygonal shape.

9. The mask frame according to claim 1, wherein a thickness of the frame body in the first direction is equal to a minimum distance between the first surface and the second surface.

10. An evaporation mask assembly, comprising:
a mask frame, having a first surface and a second surface opposite to each other, with a frame body, formed as a frame structure with an opening, and a support body, arranged in the opening and connected to the frame body, the support body comprising a plurality of evaporation apertures distributed in an array and a plurality of support units distributed around the respective evaporation apertures, the support unit comprising a supporting portion and a bonding portion extending from the supporting portion toward the evaporation aperture, the supporting portion comprising a supporting surface located on the first surface, the bonding portion comprising a bonding surface protruding to the second surface in a first direction from the first surface to the second surface, and the bonding surface and the supporting surface are distributed in a stepped shape; and
a plurality of mask strips arranged on the mask frame, the mask strip comprises two fixing structures respectively disposed at two ends thereof in its length direction and an evaporation mesh film located between the fixing structures, and the evaporation mesh film comprises a plurality of evaporation holes arranged in an array,
wherein the mask strip is fixed to the frame body through the fixing structures, the evaporation mesh film covers the first surface, and two sides of the evaporation mesh film in its length direction are arranged in contact with the supporting surfaces of the supporting portions.

11. The evaporation mask assembly according to claim 10, wherein the mask frame further comprises a plurality of auxiliary structures formed on the bonding portion and extending from the bonding surface toward the first surface, the auxiliary structures are distributed at intervals around the evaporation aperture on the bonding surface, and a sum of a thickness of the bonding portion and an extending height of the auxiliary structure in the first direction is equal to a thickness of the supporting portion.

12. The evaporation mask assembly according to claim 11, wherein the evaporation mesh film covers the first surface, and each of the two sides of the evaporation mesh film in its length direction is arranged in contact with both the supporting surfaces of the supporting portions and auxiliary supporting surfaces of the auxiliary structures located on the first surface.
